(19) United States
(12) Patent Application Publication
(10) Pub. No.: US 2026/0370979 A1
(43) Pub. Date: Nov. 19, 2026

(54) PHOTOELECTRIC CONVERSION DEVICE, PHOTOELECTRIC CONVERSION SYSTEM, AND MOVING BODY

(71) Applicant: CANON KABUSHIKI KAISHA, Tokyo (JP)

(72) Inventor: AIHIKO NUMATA, Tokyo (JP)

(21) Appl. No.: 19/674,294

(22) Filed: May 12, 2026

(30) Foreign Application Priority Data
May 16, 2025 (JP) 2025-082856

(51) Int. Cl. H04N 25/773; H10F 39/00

(52) U.S. Cl. CPC H04N 25/773; H10F 39/8053; H10F 39/8063

(57) ABSTRACT

A photoelectric conversion device that includes a converter including an APD and a counter configured to perform counting a number of signals output from the converter is provided. The counter includes first and second counters and a connector. By the connector connecting the first and second counters, the first and second counters are configurable to constitute a third counter capable of counting a sum of at least a part of a number of bits countable by the first counter and at least a part of a number of bits countable by the second counter, and in a case of constituting the third counter, the connector connects a most significant bit of the first counter and a least significant bit of the second counter, or connects a least significant bit of the first counter and a most significant bit of the second counter.

### BACKGROUND

### Field of the Technology

The present disclosure relates to a photoelectric conversion device, a photoelectric conversion system, and a moving body.

### Description of the Related Art

There is known a photoelectric conversion device that digitally counts the number of photons entering an avalanche photodiode (APD), and outputs the counted count value as a photoelectrically converted digital signal from a pixel. Japanese Patent Laid-Open No. 2019-140537 describes a solid-state image capturing element that includes a plurality of APDs sharing one microlens and counter circuits respectively corresponding to the APDs. Focusing information is obtained by comparing the count values counted by the counter circuits, and image information for generating an image is obtained by summing the count values counted by the counter circuits.

In order to acquire a plurality of pieces of count information such as focusing information and image information, the number of bits of the counter circuit may be increased, and this can lead to a large circuit scale.

### SUMMARY

Some embodiments of the present disclosure provide a technique advantageous in suppressing the circuit scale.

According to some embodiments, a photoelectric conversion device that comprises a photoelectric converter including an avalanche photodiode (APD), and a counter configured to perform counting corresponding to a number of signals output from the photoelectric converter, wherein the counter includes a first count circuit, a second count circuit, and a connection circuit, by the connection circuit connecting the first count circuit and the second count circuit, the first count circuit and the second count circuit are configurable to constitute a third count circuit capable of counting a sum of at least a part of a number of bits countable by the first count circuit and at least a part of a number of bits countable by the second count circuit, and in a case of constituting the third count circuit, the connection circuit is configured to connect a most significant bit of the first count circuit and a least significant bit of the second count circuit, or connect a least significant bit of the first count circuit and a most significant bit of the second count circuit, is provided.

Features of the present disclosure will become apparent from the following description of embodiments with reference to the attached drawings. The following description of embodiments is described by way of example.

### BRIEF DESCRIPTION OF THE DRAWINGS

FIG. 1 is a view schematically showing a configuration example of a photoelectric conversion device according to an embodiment;

FIG. 2 is a view schematically showing the configuration of the sensor board of the photoelectric conversion device according to the embodiment;

FIG. 3 is a view schematically showing the configuration of the circuit board of the photoelectric conversion device according to the embodiment;

FIG. 4 is a view showing a configuration example of a pixel according to the embodiment;

FIG. 5 is a view for explaining an example of the operation of a pixel circuit according to the embodiment;

FIG. 6 is a view for explaining a method of acquiring the count information of the photoelectric conversion device according to the embodiment;

FIGS. 7A and 7B are views showing a configuration example of the pixel circuit of a photoelectric conversion device according to an embodiment;

FIG. 8 is a view for explaining the control method of the pixel circuit shown in FIGS. 7A and 7B;

FIGS. 9A and 9B are views showing a configuration example of the pixel circuit of a photoelectric conversion device according to an embodiment;

FIG. 10 is a view for explaining the control method of the pixel circuit shown in FIGS. 9A and 9B;

FIG. 11 is a view showing the configuration of the pixel circuit of a photoelectric conversion device according to an embodiment;

FIG. 12 is a view for explaining the control method of the pixel circuit shown in FIG. 11;

FIGS. 13A and 13B are views showing a configuration example of the pixel circuit of a photoelectric conversion device according to an embodiment;

FIG. 14 is a view for explaining the control method of the pixel circuit shown in FIGS. 13A and 13B;

FIG. 15 is a view showing an example of a photoelectric conversion system using the photoelectric conversion device according to the embodiment;

FIGS. 16A and 16B are views showing an example of a photoelectric conversion system using the photoelectric conversion device according to the embodiment;

FIG. 17 is a view showing an example of a photoelectric conversion system using the photoelectric conversion device according to the embodiment; and

FIGS. 18A and 18B are views each showing an example of a photoelectric conversion system using the photoelectric conversion device according to the embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the following description, terms (for example, “upper”, “lower”, “right”, “left” and other terms including these terms) representing specific directions or positions are used, as necessary. These terms are used for easy understanding of the embodiments with reference to the accompanying drawings, and the meanings of the terms do not limit the technical scope of the present disclosure.

In this specification, a planar view is viewing from a direction perpendicular to the light incident surface of a semiconductor layer. A sectional view is viewing a plane in the direction perpendicular to the light incident surface of the semiconductor layer. If the light incident surface of the semiconductor layer is rough microscopically, the planar view is defined with reference to the light incident surface of the semiconductor layer when viewed macroscopically.

In the following description, the anode of an avalanche photodiode (APD) is set at a fixed potential and a signal is extracted from the cathode side. Therefore, a semiconductor region of the conductivity type where a charge of the same polarity as that of a signal charge serves as a majority carrier is an n-type semiconductor region, and a semiconductor region of the conductivity type where a charge of a polarity different from that of a signal charge serves as a majority carrier is a p-type semiconductor region. However, the present disclosure is not limited to this, and is established even in a case where the cathode of the APD is set at a fixed potential and a signal is extracted from the anode side. In this case, a semiconductor region of the conductivity type where a charge of the same polarity as that of a signal charge serves as a majority carrier is a p-type semiconductor region, and a semiconductor region of the conductivity type where a charge of a polarity different from that of a signal charge serves as a majority carrier is an n-type semiconductor region. A case where one node of the APD is set at a fixed potential will be explained below, but the potentials of two nodes may vary.

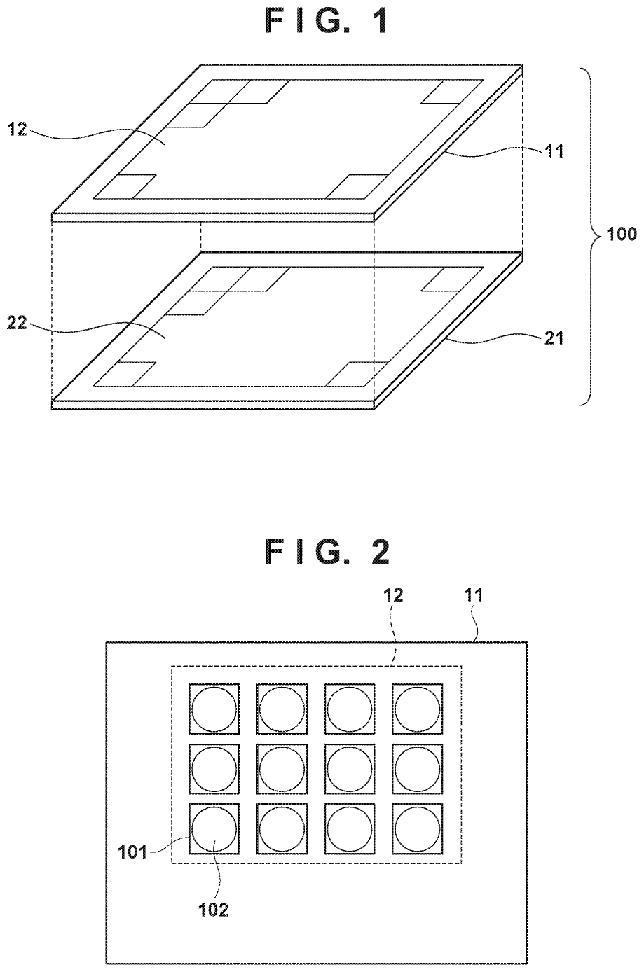

First, the configuration of a photoelectric conversion device and a photoelectric conversion device driving method according to an embodiment, which is common to respective embodiments, will be described with reference to FIGS. 1 to 5. FIG. 1 is a view showing a configuration example of the photoelectric conversion device according to the embodiment. FIG. 1 shows a stacked type photoelectric conversion device 100. The photoelectric conversion device 100 can be formed by stacking two chips of a sensor chip 11 and a circuit chip 21 and electrically connecting them. The sensor chip 11 is arranged with a pixel region 12, and the circuit chip 21 is arranged with a circuit region 22 for processing signals detected in the pixel region 12.

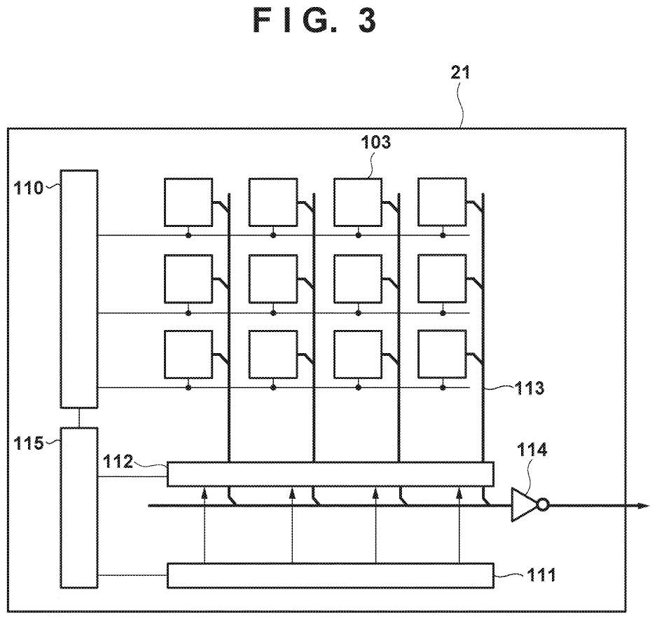

FIG. 2 is a view showing a configuration example of the sensor chip 11. In the pixel region 12, pixels 101 each including a photoelectric converter 102 including an APD are arranged in an array so as to form a plurality of rows and a plurality of columns. FIG. 3 is a view showing a configuration example of the circuit chip 21. The circuit chip 21 includes pixel circuits 103 that process charges photoelectrically converted by the photoelectric converters 102 shown in FIG. 2, a readout circuit 112, a control pulse generation unit 115, a horizontal scanning circuit 111, output lines 113, and a vertical scanning circuit 110. The photoelectric converter 102 shown in FIG. 2 and the pixel circuit 103 shown in FIG. 3 can be electrically connected via a connection wiring pattern provided for each pixel 101.

The vertical scanning circuit 110 supplies a control pulse to each pixel 101 in accordance with a control pulse supplied from the control pulse generation unit 115. For example, a logic circuit such as a shift register or an address decoder can be used for the vertical scanning circuit 110.

A signal output from the photoelectric converter 102 of each pixel 101 is processed by the pixel circuit 103. A counter, a memory, and the like are provided in the pixel circuit 103. The memory holds a digital value.

The horizontal scanning circuit 111 inputs, to the pixel circuits 103, a control pulse for sequentially selecting respective columns in order to read out signals from the memories of the respective pixels 101 holding digital signals. As for a column selected by the horizontal scanning circuit 111, a signal is output to the output line 113 from the pixel circuit 103 of the pixel selected by the vertical scanning circuit 110. The signal output to the output line 113 is output via an output circuit 114 to a recording unit or a signal processing unit outside the photoelectric conversion device 100.

In the configuration shown in FIG. 2, the pixels 101 are arranged in a two-dimensional array in the pixel region 12, but the present disclosure is not limited thereto. For example, the pixels 101 may be arrayed one-dimensionally (in a line) in the pixel region 12. The function of the pixel circuit 103 need not always be provided one by one in all the pixels 101. For example, one pixel circuit 103 may be shared by multiple pixels 101 to sequentially perform signal processing.

The photoelectric conversion device 100 according to the present disclosure can acquire a plurality of pieces of count information. Therefore, in accordance with the type of count information to be acquired, one pixel 101 may include multiple photoelectric converters 102. This will be described in detail in each embodiment.

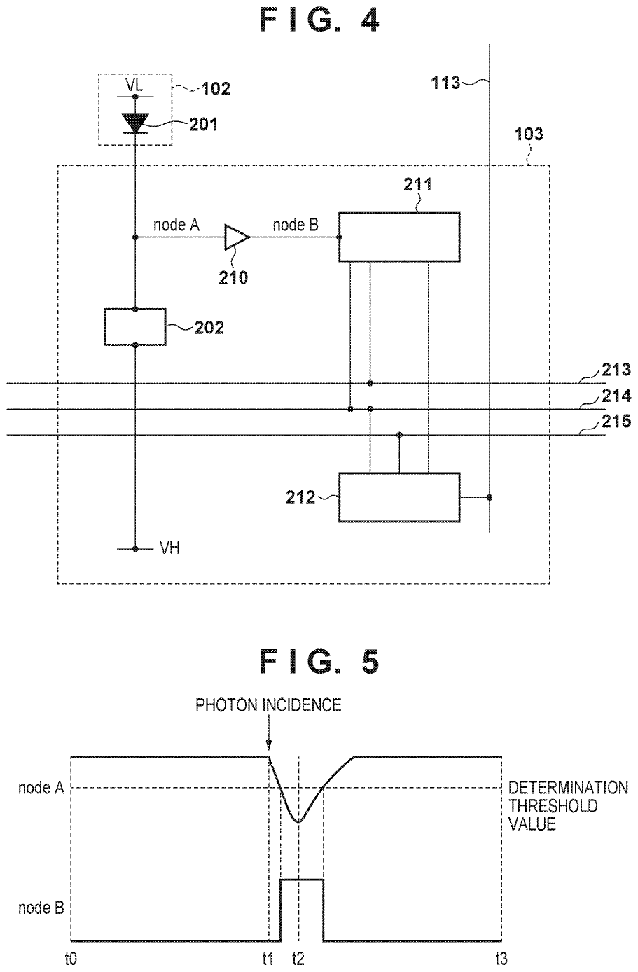

FIG. 4 shows an example of the block diagram including the equivalent circuits shown in FIGS. 2 and 3. In FIG. 2, the photoelectric converter 102 including an APD 201 shown in FIG. 4 is provided in the sensor chip 11, and the remaining components are provided in the circuit chip 21.

The APD 201 generates a charge pair corresponding to incident light by photoelectric conversion. A voltage VL is supplied to the anode of the APD 201. A voltage VH, which is higher than the voltage VL supplied to the anode, is supplied to the cathode of the APD 201. A reverse bias voltage is supplied to the anode and the cathode so that the APD 201 performs an avalanche multiplication operation. By setting the state in which such a voltage is supplied, charges generated by incident light cause avalanche multiplication, generating an avalanche current.

In a case of supplying the reverse bias voltage, there is a Geiger mode in which the APD is operated when the potential difference between the anode and the cathode is higher than the breakdown voltage, and a linear mode in which the APD is operated when the potential difference between the anode and the cathode is around or lower than the breakdown voltage. An APD operated in the Geiger mode is called an SPAD. For example, the voltage VL is −30 V and the voltage VH is 1 V.

The pixel circuit 103 can include a quench element 202, a waveform shaping circuit 210, a counter circuit 211, and a memory 212. The quench element 202 is connected between the APD 201 and a power supply line for supplying the voltage VH. The quench element 202 is formed by a MOS transistor, a resistance element, or the like. When a photocurrent is multiplied by avalanche multiplication in the APD 201, a current generated by the multiplied charges flows to the connection node between the APD 201 and the quench element 202. Due to the voltage drop caused by this current, the cathode potential of the APD 201 drops, and the APD 201 no longer forms an electron avalanche. Due to this, the avalanche multiplication in the APD 201 stops. Thereafter, since the voltage VH is supplied to the cathode of the APD 201 via the quench element 202, the voltage supplied to the cathode of the APD 201 returns to the voltage VH. That is, the operation region of the APD 201 enters the Geiger mode again. In this manner, the quench element 202 functions as a load circuit (quench circuit) at the time of signal multiplication by avalanche multiplication, and serves to suppress avalanche multiplication by suppressing the voltage supplied to the APD 201 (quenching operation). The quench element 202 also serves to set the operation region of the APD 201 to the Geiger mode again after suppressing avalanche multiplication.

The waveform shaping circuit 210 outputs a pulse signal by shaping the potential change of the cathode of the APD 201 obtained at the time of detection of a photon. As the waveform shaping circuit 210, for example, an inverter circuit is used. FIG. 4 shows a configuration example in which one inverter is used as the waveform shaping circuit 210, but a circuit obtained by serially connecting a plurality of inverters may be used, or another circuit having the waveform shaping effect may be used.

The counter circuit 211 counts a pulse signal output from the waveform shaping circuit 210, and holds a counted count value. When a control pulse pRES is supplied via a driving line 213, the count value held in the counter circuit 211 is reset.

The memory 212 temporarily stores the count value held in the counter circuit 211. The memory 212 outputs a signal corresponding to the temporarily stored count value to the output line 113. More specifically, when a control pulse pREAD is supplied from the vertical scanning circuit 110 shown in FIG. 1 via a driving line 214 shown in FIG. 4, the count value held in the counter circuit 211 is read out to the memory 212. When a control pulse pSEL is supplied from the vertical scanning circuit 110 via a driving line 215, electrical connection/non-connection between the counter circuit 211 and the output line 113 is switched. When the counter circuit 211 is connected to the output line 113, the signal corresponding to the count value is output to the output line 113.

A switch such as a transistor may be arranged between the quench element 202 and the APD 201 or between the photoelectric converter 102 and the pixel circuit 103 to switch electrical connection. Similarly, a switch such as a transistor may be arranged between the APD 201 and the power supply line for supplying the voltage VL thereto to switch electrical connection.

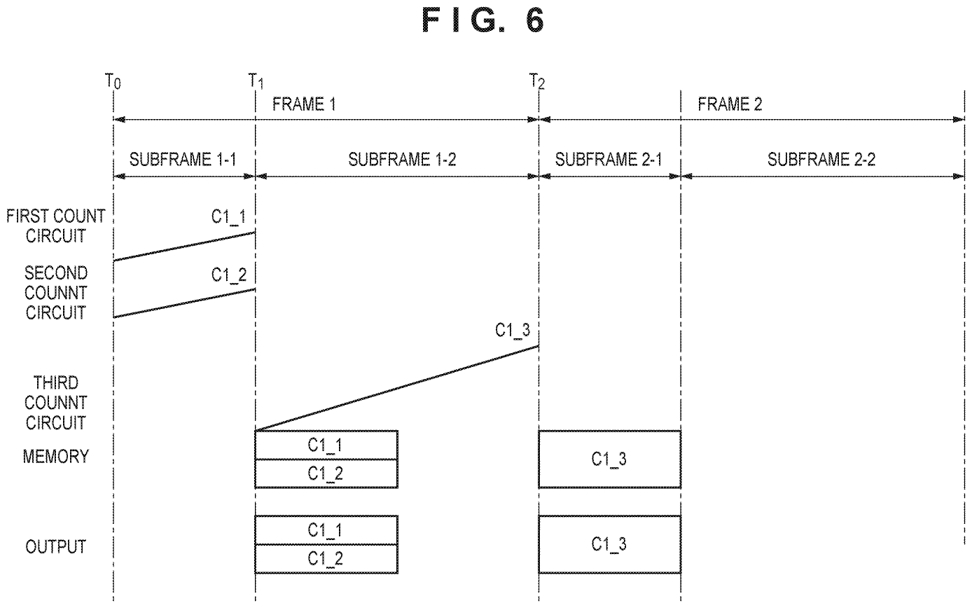

FIG. 5 is a view schematically showing the relationship between the operation of the APD 201 and the output signal. FIG. 5 shows the waveform change at a node A and the waveform change at a node B shown in FIG. 4.

During a period from time t0 to time t1, a potential difference of voltage VH voltage VL is applied to the APD 201. When a photon enters at time t1, an avalanche multiplication current flows through the quench element 202, thereby dropping the voltage of the node A. When the voltage drop amount further increases and the potential difference applied to the APD 201 decreases, the avalanche multiplication in the APD 201 stops, and the voltage level of the node A does not drop any more from a predetermined value. After that, a current compensating for the voltage drop from the voltage VH flows through the node A. At time t3, the node A is settled at the original potential level. At this time, a portion of the output waveform at the node A exceeding a given threshold is waveform-shaped by the waveform shaping circuit 210, and output as a pulse signal to the node B.

With reference to a conceptual diagram of FIG. 6, a method of acquiring a plurality of pieces of count information by using the photoelectric conversion device 100 according to the present disclosure will be described. The photoelectric conversion device 100 according to the present disclosure executes a plurality of unit sequences (to be sometimes referred to as frames hereinafter). One frame is constituted by a plurality of subframes. In the example shown in FIG. 6, a frame 1 includes a subframe 1-1 from time T₀ to time T₁, and a subframe 1-2 from time T₁ to time T₂.

In the subframe 1-1, the first count circuit is used to perform counting corresponding to the number of pulses of the first signal output from the photoelectric converter 102, and the second count circuit is used to perform counting corresponding to the number of pulses of the second signal output from the photoelectric converter 102. FIG. 6 shows that the count values of the first count circuit and the second count circuit increase from time T₀ to time T₁. At time T₁ during a period from the start to end of the frame 1, a connection circuit is used to connect the first count circuit and the second count circuit, thereby causing the first count circuit and the second count circuit to constitute the third count circuit. In the subframe 1-2 from time T₁ to time T₂, the third count circuit constituted by connecting the first count circuit and the second count circuit is used to perform counting corresponding to the number of pulses of the third signal.

In this manner, by using the connection circuit to temporally switch the configuration of the count circuits, it is possible to acquire not only the first signal and the second signal by using the first count circuit and the second count circuit but also the third signal by using the third count circuit. The specific configuration of the count circuits and connection circuit will be described in each embodiment described below.

The signals acquired in the subframes 1-1 and 1-2 are temporarily stored in the memory 212. The signals temporarily stored in the memory 212 are sequentially output from the photoelectric conversion device 100 via the buffer of the readout circuit 112.

In the first embodiment according to the present disclosure, a photoelectric conversion device 100 will be described in which two photoelectric conversion elements (an APD 201a and an APD 201b) are arranged for each pixel 101 (photoelectric converter 102), and one count circuit is provided for each of the APDs 201a and 201b. The photoelectric conversion device 100 according to this embodiment can acquire focusing information from the first signal and the second signal, and acquire image information from the third signal.

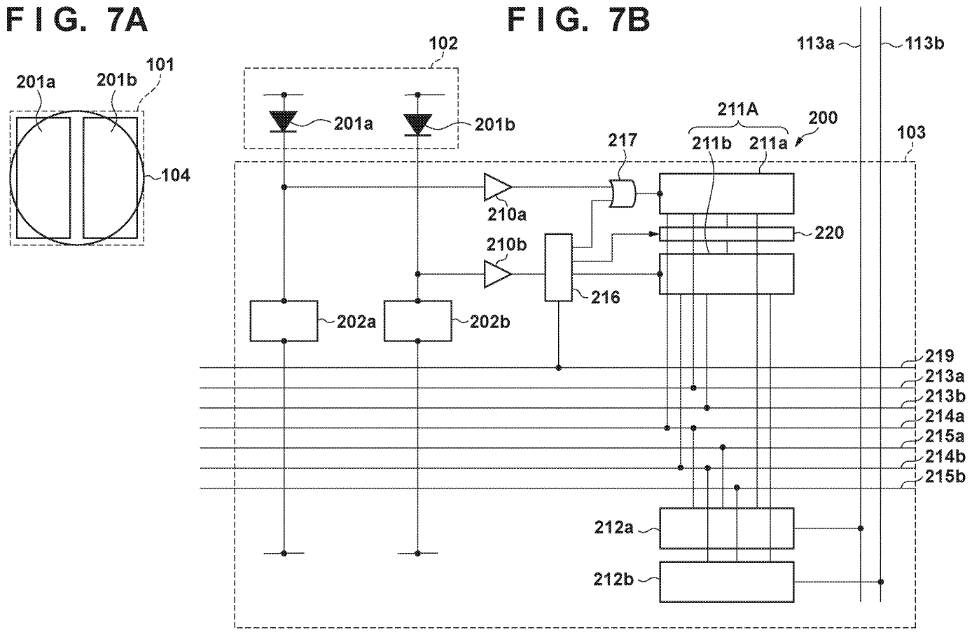

FIGS. 7A and 7B are views showing a configuration example of the photoelectric converter 102 and a pixel circuit 103 of the photoelectric conversion device 100 according to this embodiment. As shown in FIG. 7A, the photoelectric conversion device 100 includes two APDs 201a and 201b arrayed in a horizontal direction and sharing one microlens 104 for each pixel 101. The components of the pixel circuit 103 such as a quench element 202, a waveform shaping circuit 210, and a memory 212 are arranged so as to correspond to each of the APDs 201a and 201b. That is, in this specification, the photoelectric converter 102 including the plurality of APDs, each of which has a role of converting light into an electrical signal, and a barrier region therebetween in the pixel 101 is described as a photoelectric converter.

A counter 200 including counter circuits 211a and 211b and a connection circuit 220 is arranged in the pixel circuit 103. The counter circuit 211a is an example of the above-described first count circuit, and counts the number of signals output from the APD 201a (the number of pulse signals output from the APD 201a and shaped by a waveform shaping circuit 210a). It can also be said that the counter circuit 211a counts the number of photons having entered the APD 201a. The counter circuit 211b is an example of the above-described second count circuit, and counts the number of signals output from the APD 201b (the number of pulse signals output from the APD 201b and shaped by a waveform shaping circuit 210b). It can also be said that the counter circuit 211b counts the number of photons having entered the APD 201b. Here, the following description will be given assuming that each of the counter circuits 211a and 211b is an 8-bit counter circuit.

The connection circuit 220 is a circuit for connecting the counter circuits 211a and 211b to use them as a 16-bit counter circuit 211A. The connection circuit 220 connects the counter circuit 211a and the counter circuit 211b. It can also be said that the counter circuit 211a and the counter circuit 211b can constitute the counter circuit 211A capable of counting the sum of the number of bits countable by the counter circuit 211a and the number of bits countable by the counter circuit 211b. The counter circuit 211A is an example of the above-described third count circuit.

When constituting the counter circuit 211A, the connection circuit 220 connects the most significant bit of the counter circuit 211a and the least significant bit of the counter circuit 211b, or connects the least significant bit of the counter circuit 211a and the most significant bit of the counter circuit 211b. In the configuration shown in FIG. 7, the counter circuit 211a constitutes the lower bits of the counter circuit 211A, and the counter circuit 211b constitutes the upper bits of the counter circuit 211A. However, the upper bits and the lower bits may be interchanged, or another connection may be performed. Note that the configuration of using two counter circuits 211a and 211b as circuits for the upper bits and lower bits, respectively, and connecting these by the connection circuit 220 is advantageous in suppressing the circuit scale. As the connection circuit 220, for example, a flip flop circuit may be used. In this case, the inverted output of the most significant bit of the lower bit counter circuit may be connected to the input of the least significant bit of the upper bit counter circuit.

A switch 216 is a switch for switching whether the counter circuits 211a and 211b are used as the 8-bit counter circuits, respectively, or used as the 16-bit counter circuit which is the counter circuit 211A. When the switch 216 is in the first state (for example, OFF state), the counter circuits 211a and 211b function as the 8-bit counter circuits, respectively. On the other hand, when the switch 216 is in the second state (for example, ON state), the counter circuits 211a and 211b are connected via the connection circuit 220 and function as the 16-bit counter circuit 211A.

In the photoelectric conversion device 100 according to this embodiment, the switch 216 also has a role of switching the connection between the cathode of the APD 201b and each of the counter circuits 211a and 211b. When the switch 216 is in the OFF state, the cathode of the APD 201b is connected to the counter circuit 211b. At the same time, the input from the switch 216 to an OR circuit 217 is fixed at Low. On the other hand, when the switch 216 is in the ON state, the cathode of the APD 201b is connected to one input of the OR circuit 217. The other input of the OR circuit 217 is connected to the cathode of the APD 201a. The switch 216 is connected to a driving line 219, and controlled to the ON state or the OFF state by a control pulse supplied from the vertical scanning circuit 110 to the driving line 219.

With this configuration, when the switch 216 is in the OFF state, the counter circuit 211a counts a signal corresponding to incidence of a photon to the APD 201a, and the counter circuit 211b counts a signal corresponding to incidence of a photon to the APD 201b. On the other hand, when the switch 216 is in the ON state, if a photon enters one of the APD 201a and the APD 201b, regardless of which of the APD 201a and the APD 201b the photon enters, the count value at the counter circuit 211A increases by 1. In this manner, by the connection circuit 220 controlling the connection state between the counter circuit 211a and the counter circuit 211b, a plurality of pieces of count information can be acquired.

When the counter circuit 211a counts a signal corresponding to incidence of a photon to the APD 201a and the counter circuit 211b counts a signal corresponding to incidence of a photon to the APD 201b, focusing information can be acquired by comparing the values thereof. When the connection circuit 220 is used to cause the counter circuits 211a and 211b to configure the counter circuit 211A, and the counter circuit 211A counts signals corresponding to incidence of photons to the APD 201a and the APD 201b, image information can be acquired.

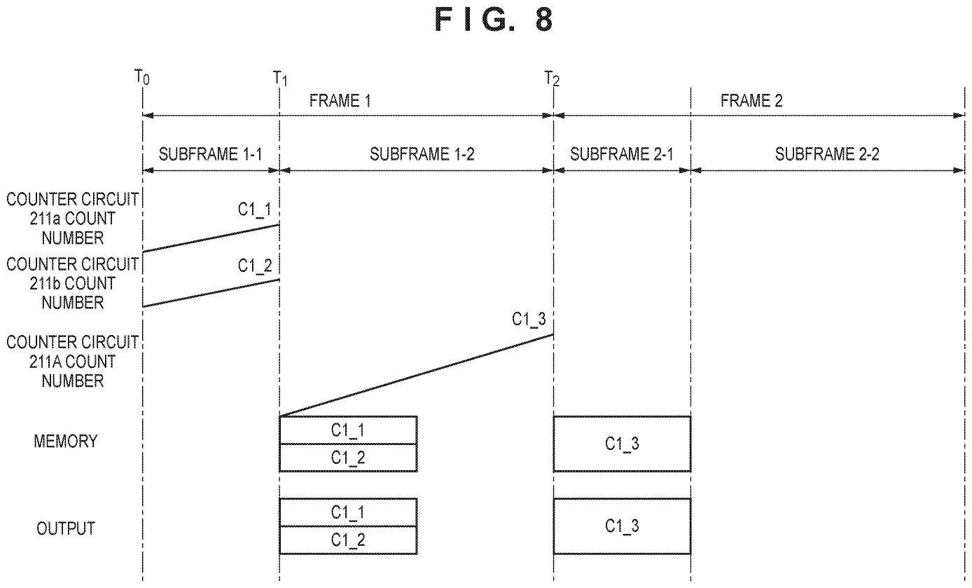

FIG. 8 is a view for explaining a method of acquiring focusing information and image information by using the photoelectric conversion device 100 including the pixel circuit 103 shown in FIGS. 7A and 7B. In the photoelectric conversion device 100 according to this embodiment, at time T₀ which is the start time of a frame 1, the values of the counter circuits 211a and 211b are reset, and the switch 216 of the connection circuit 220 is set in the OFF state. Then, from time T₀, the counter circuit 211a starts to count the number of signals (corresponding to the above-described first signal) C1_1 corresponding to incidence of photons to the APD 201a. At the same time, the counter circuit 211b starts to count the number of signals (corresponding to the above-described second signal) C1_2 corresponding to incidence of photons to the APD 201b. In a subframe 1-1 from time T₀ to time T₁, the counter circuit 211a counts the signals output from the APD 201a, and the counter circuit 211b counts the signals output from the APD 201b.

At time T₁ during the frame 1, a control pulse pREAD is supplied from the vertical scanning circuit 110 via driving lines 214a and 214b, and the count values C1_1 and C1_2 of the counter circuits 211a and 211b are read out to memories 212a and 212b. Then, a control pulse pRES is supplied from the vertical scanning circuit 110 via driving lines 213a and 213b, and the count values of the counter circuits 211a and 211b are reset. When a control pulse pSEL is supplied from the vertical scanning circuit 110 via driving lines 215a and 215b, the first signal and the second signal read out to the memories 212a and 212b are sequentially output from the photoelectric conversion device 100 via the buffer of a readout circuit 112. In accordance with the maximum count numbers of the counter circuits 211a and 211b, the memories 212a and 212b may be memories of 8 or more bits.

When the counter circuits 211a and 211b are reset, the switch 216 is set in the ON state in accordance with the control pulse supplied from the vertical scanning circuit 110 to the driving line 219. This causes the counter circuits 211a and 211b to configure the counter circuit 211A. From time T₁, the 16-bit counter circuit 211A starts to count the number of signals (corresponding to the above-described third signal) C1_3 corresponding to incidence of photons to the APD 201a and 201b. In a subframe 1-2 from time T₁ to time T₂, the counter circuit 211A counts signals output from the APD 201a and the APD 201b.

At time T₂ which is the end time of the frame 1, the count value C1_3 of the counter circuit 211A is read out to a memory 212. Then, the count value of the counter circuit 211A is reset, and the switch 216 is set in the OFF state. Then, a counting operation as in the frame 1 is started in a frame 2. The third signal read out to the memory 212 is sequentially output from the photoelectric conversion device 100 via the buffer of the readout circuit 112.

As described above, the maximum count number (16 bits) of the counter circuit 211A is larger than the maximum count number (8 bits) of each of the counter circuits 211a and 211b. Therefore, the memories 212a and 212b may be connected to configure one memory 212A. With this, it is unnecessary to provide a 16-bit memory for the third signal separately from the memories 212a and 212b, and the 8-bit memories 212a and 212b for the first and second signals can be used. As a result, an increase in memory circuit scale can be suppressed. More specifically, as is the case with the counter circuits 211a and 211b, a switch (not shown) for connecting the memory 212a and the memory 212b is arranged in the pixel circuit 103, and a pulse signal is supplied from the vertical scanning circuit 110 via a driving line. This may control the connection between the memory 212a and the memory 212b.

In this manner, in the photoelectric conversion device 100 according to this embodiment, focusing information can be acquired from the first count information and the second count information acquired in the subframe 1-1, and image information can be acquired from the third count information acquired in the subframe 1-2. The effect of this embodiment will be described below in comparison with a photoelectric conversion device of a comparative example. The photoelectric conversion device of the comparative example includes one microlens and two APDs for each pixel 101 (photoelectric converter 102), and two counter circuits are provided for each APD. The photoelectric conversion device of the comparative example can have a configuration obtained by removing the connection circuit 220 and the switch 216 from the photoelectric conversion device 100 according to this embodiment. The photoelectric conversion device of the comparative example acquires focusing information by comparing the numbers of signals counted by two counter circuits. The photoelectric conversion device of the comparative example acquires image information by summing the numbers of signals counted by two counter circuits.

When image information is acquired by using the photoelectric conversion device of the comparative example and summing the numbers of signals counted by two counter circuits, in order to acquire 16-bit image information, each counter circuit requires the circuit scale of at least 15 or more bits. On the other hand, in the photoelectric conversion device 100 according to this embodiment, by using the connection circuit 220 to temporally switch the role of the counter 200, the circuit scale required for each of the counter circuits 211a and 211b can be reduced to 8 bits. That is, the photoelectric conversion device 100 according to this embodiment can suppress the circuit scale as compared to the photoelectric conversion device of the comparative example.

As shown in FIG. 8, in order to improve the accuracy of focusing information, time T₁ needs to be a timing when the counter circuits 211a and 211b do not saturate in the subframe 1-1. Hence, when L1 [msec] is the period length of the subframe 1-1 (the length from time T₀ to time T₁), L2 [msec] is the period length of the subframe 1-2 (length from time T₀ to time T₁), B1 [bit] is the number of bits countable by the counter circuit 211a, B2 [bit] is the number of bits countable by the counter circuit 211b, and min(B1, B2) is the smaller one of B1 and B2, the following formula (1) may be satisfied:

L1≤(2^{min(B1,B2)}/2^{B1+B2})×L2 (1)

When the sensitivity of the photoelectric converter 102a and the sensitivity of the photoelectric converter 102b are approximately the same, the accuracy of focusing information to be acquired can improve. Accordingly, the number of bits countable by the counter circuit 211a and the number of bits countable by the counter circuit 211b may also be the same. Hence, assuming that both the number of bits countable by the counter circuit 211a and the number of bits countable by the counter circuit 211b are indicated by B [bit], the above-described formula (1) can be rewritten as:

L1≤(½^{B})×L2 (1′)

FIG. 8 shows an example of the operation in which the first signal and the second signal are acquired in the subframe 1-1, and the third signal is acquired in the subframe 1-2. However, in one frame, the subframe for acquiring the third signal may be arranged first, followed by the subframe for acquiring the first signal and the second signal. However, for example, in a case of using focusing information in focus detection, acquiring focusing information first from the first signal and the second signal can shorten the time required to achieve focusing, and improve the characteristics of the photoelectric conversion device 100. Furthermore, one frame may be constituted by three or more subframes, and the connection between the counter circuits 211a and 211b may be switched a plurality of times by the connection circuit 220.

Here, the control by the connection circuit 220 is not required in all the pixels 101 arranged in a pixel region 12. For example, the control by the connection circuit 220 may be performed only in the pixels 101 requiring focusing information, and the switch 216 of the connection circuit 220 may be constantly kept in the ON state in the remaining pixels 101 to acquire only image information. In that case, if the accumulation time of the pixel 101 where both focusing information and image information are acquired and the accumulation time of the pixel 101 where only image information is acquired are equal, the processing amount for processing the signals output from the respective pixels 101 can be suppressed. Therefore, even in the pixel where only image information is acquired, the number of signals corresponding to incidence of photons to the APDs 201a and 201b may be counted from time T₁ to time T₂. For example, similar to the pixel 101 where both focusing information and image information are acquired, the counter circuit 211A may be reset at time T₁.

The example has been described above in which all the 8 bits of the counter circuit 211a and all the 8 bits of the counter circuit 211b are connected to function as the counter circuit 211A. However, only a part of connection of the counter circuit may be switched. That is, it is sufficient that the third count circuit capable of counting a sum of at least a part of the number of bits countable by the first count circuit and at least a part of the number of bits countable by the second count circuit, can be constituted.

For example, if the counter circuit 211A requires 12 bits, 6 bits of the counter circuit 211a and 6 bits of the counter circuit 211b may be connected, or all bits of the counter circuit 211a and 4 bits of the counter circuit 211b may be connected.

Connecting all the 8 bits of the counter circuit 211a and all the 8 bits of the counter circuit 211b increases the number of bits of the counter circuit 211A, and this improves the signal-to-noise ratio of an image signal. On the other hand, connecting a part of the counter circuit 211a and a part of the counter circuit 211b can decrease the circuit scale.

Next, a photoelectric conversion device 100 according to the second embodiment of the present disclosure will be described. In the embodiment described above, the example has been described in which each pixel 101 includes two APDs 201a and 201b, that is, the pixel 101 is a so-called DualPixel. However, the present disclosure is not limited to this, and the pixel 101 may include three or more APDs 201. The configuration different from the above-described embodiment will mainly be described below, and a description of the configuration that may be the same as in the above-described embodiment will appropriately be omitted.

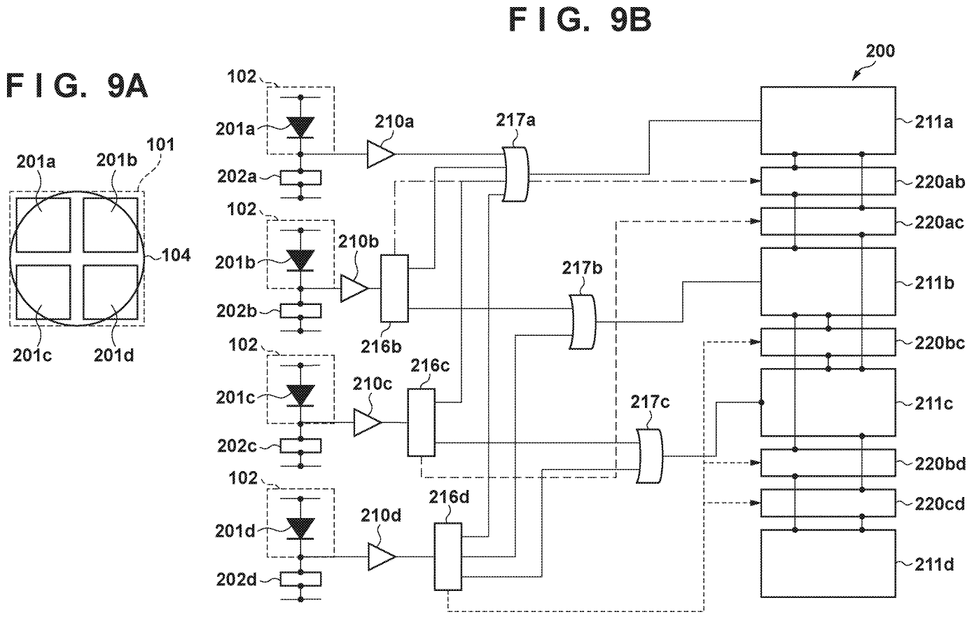

The photoelectric conversion device 100 according to this embodiment has a so-called QuadPixel configuration as shown in FIG. 9A. That is, each pixel 101 includes one microlens 104, and a photoelectric converter 102 includes four APDs 201a, 201b, 201c, and 201d. As shown in FIG. 9B, in a counter 200 of the pixel 101, counter circuits 211a, 211b, 211c, and 211d are arranged so as to correspond to the APDs 201a, 201b, 201c, and 201d, respectively. Furthermore, a connection circuit 220 arranged in the counter 200 is configured to be capable of connecting the counter circuits 211a, 211b, 211c, and 211d to each other.

In this manner, four APDs 201a, 201b, 201c, and 201d are arranged at the top, bottom, left, and right in the pixel 101 in FIG. 9A. This enables acquisition of signals corresponding to light beams passing through a plurality of pupil regions divided in vertical direction and signals corresponding to light beams passing through a plurality of pupil regions divided in horizontal direction. The reason for this will be described below.

For example, as shown in FIG. 7A, in the photoelectric conversion device 100 that performs focusing by using signals corresponding to light beams respectively passing through a plurality of pupil regions divided in the horizontal direction, it is possible to perform focusing with high accuracy with respect to an object such as a vertical line having large changes in the horizontal direction. However, it is difficult to perform focusing with high accuracy with respect to an object such as a horizontal line having small changes in the horizontal direction.

To the contrary, the configuration shown in FIG. 9A can acquire signals corresponding to light beams respectively passing through a plurality of pupil regions divided in the vertical and horizontal directions, so that signals used in focusing can be selected in accordance with the direction of the large change. This can implement highly accurate focusing regardless of the object.

More specifically, by comparing signals acquired using the APDs 201a and 201b and signals acquired using the APDs 201c and 201d, signals corresponding to light beams respectively passing through a plurality of pupil regions divided in the horizontal direction can be acquired. By comparing signal acquired using the APDs 201a and 201b and signal acquired using the APDs 201c and 201d, signals corresponding to light beams respectively passing through a plurality of pupil regions divided in the vertical direction can be acquired.

Next, with reference to FIG. 9B, connection control of the counter circuits 211a, 211b, 211c, and 211d using the connection circuit 220 will be described. First, a case of acquiring signals corresponding to light beams respectively passing through the plurality of pupil regions divided in the horizontal direction will be described. In this case, switches 216b, 216c, and 216d connect the cathodes of the APD 201a and APD 201c to the inputs of an OR circuit 217a, and connect the cathodes of the APD 201b and APD 201d to the inputs of an OR circuit 217b. A connection circuit 220ac connects the 4-bit counter circuit 211a and the 4-bit counter circuit 211c to cause them to function as an 8-bit counter circuit 211L. Similarly, a connection circuit 220bd connects the 4-bit counter circuit 211b and the 4-bit counter circuit 211d to cause them to function as an 8-bit counter circuit 211R. As a result, signals corresponding to light beams respectively passing through the plurality of pupil regions divided in the horizontal direction can be acquired. The configuration for connecting the counter circuits in this manner may be referred to as a horizontal connection below.

Next, a case of acquiring signals corresponding to light beams respectively passing through the plurality of pupil regions divided in the vertical direction will be described. In this case, the switches 216b, 216c, and 216d connect the cathodes of the APD 201a and APD 201b to the inputs of the OR circuit 217a, and connect the cathodes of the APD 201c and APD 201d to the inputs of an OR circuit 217c. A connection circuit 220ab connects the 4-bit counter circuit 211a and the 4-bit counter circuit 211b to cause them to function as an 8-bit counter circuit 211T. Similarly, a connection circuit 220cd connects the 4-bit counter circuit 211c and the 4-bit counter circuit 211d to cause them to function as an 8-bit counter circuit 211B. As a result, signals corresponding to light beams respectively passing through the plurality of pupil regions divided in the vertical direction can be acquired. The configuration for connecting the counter circuits in this manner may be referred to as a vertical connection below.

Next, a case of acquiring image information will be described. The switches 216b, 216c, and 216d connect the cathodes of all the APDs 201a, 201b, 201c, and 201d to the inputs of the OR circuit 217a. The connection circuit 220ab connects the counter circuit 211a and the counter circuit 211b, a connection circuit 220bc connects the counter circuit 211b and the counter circuit 211c, and the connection circuit 220cd connects the counter circuit 211c and the counter circuit 211d. This connects all the 4-bit counter circuits 211a, 211b, 211c, and 211d, thereby causing them to function as the 16-bit counter circuit 211A. As a result, image information can be acquired. The configuration for connecting the counter circuits in this manner may be referred to as a full connection below.

As described above, it can also be said that each of the first and second count circuits (counter circuits) having a role of counting signals corresponding to light beams respectively passing through the plurality of pupil regions divided in the horizontal direction in the first embodiment described above is constituted by two count circuits (counter circuits) in this embodiment. That is, the counter circuit 211a shown in FIG. 7B is constituted by the counter circuits 211a and 211c shown in FIG. 9B. Similarly, the counter circuit 221b shown in FIG. 7B is constituted by the counter circuits 211b and 211d shown in FIG. 9B.

As shown in FIG. 9B, the connection circuit 220 includes the connection circuit 220ab that connects the counter circuit 211a and the counter circuit 211b, and the connection circuit 220cd that connects the counter circuit 211c and the counter circuit 211d. This enables counting of signals corresponding to light beams respectively passing through the plurality of pupil regions divided in the vertical direction. Although a memory 212, driving lines 213, 214, and 215, and the like are not shown in FIG. 9B, connections thereof may use a configuration similar to the configuration shown in FIG. 7B.

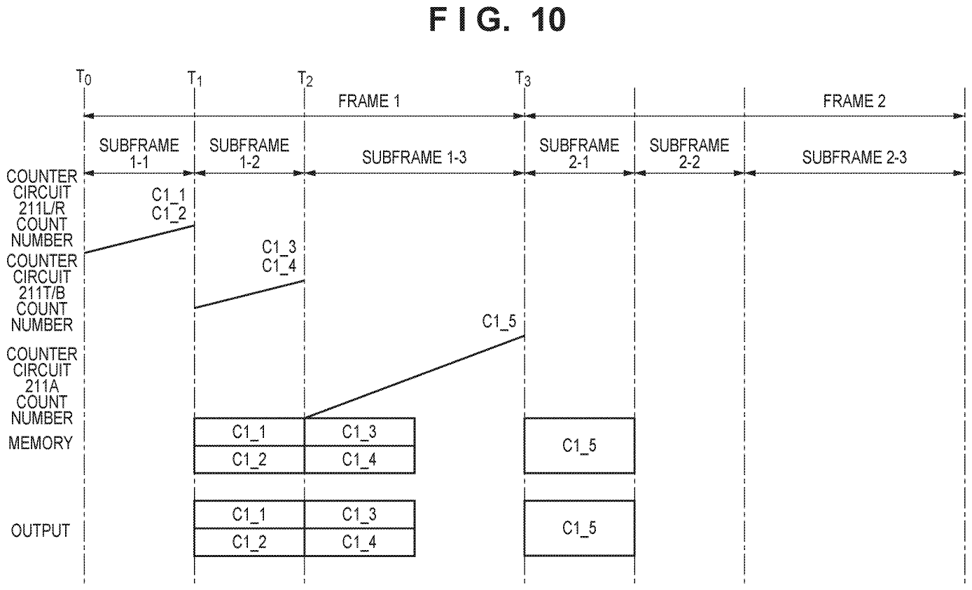

FIG. 10 is a view for explaining a method of acquiring focusing information and image information by using the photoelectric conversion device 100 having the configuration shown in FIGS. 9A and 9B. At time T₀ which is the start time of a frame 1, the values of the counter circuits 211a, 211b, 211c, and 211d are reset, and the connection circuit 220 sets the counter circuits 211a, 211b, 211c, and 211d in the horizontal connection. Then, in a subframe 1-1 starting from time T₀, the counter circuit 211L counts the number of signals (count value C1_1) corresponding to incidence of photons to the APDs 201a and 201c. At the same time, the counter circuit 211R counts the number of signals (count value C1_2) corresponding to incidence of photons to the APDs 201b and 201d.

At time T₁ during the frame 1, the count values C1_1 and C1_2 of the counter circuits 211L and 211R are read out to the memory 212. The readout count values C1_1 and C1_2 are sequentially output from the photoelectric conversion device 100 via the buffer of a readout circuit 112. In addition, the count values of the counter circuits 211L and 211R are reset, and the connection circuit 220 sets the counter circuits 211a, 211b, 211c, and 211d in the vertical connection. In a subframe 1-2 starting from time T₁, the counter circuit 211T counts the number of signals (count value C1_3) corresponding to incidence of photons to the APDs 201a and 201b. At the same time, the counter circuit 211B counts the number of signals (count value C1_4) corresponding to incidence of photons to the APDs 201c and 201d.

At time T₂ during the frame 1, the count values C1_3 and C1_4 of the counter circuits 211T and 211B are read out to the memory 212. The readout count values C1_3 and C1_4 are sequentially output from the photoelectric conversion device 100 via the buffer of the readout circuit 112. In addition, the count values of the counter circuits 211T and 211B are reset, and the connection circuit 220 sets the counter circuits 211a, 211b, 211c, and 211d in the total connection. In a subframe 1-3 starting from time T₂, the counter circuit 211A counts the number of signals (count value C1_5) corresponding to incidence of photons to the APDs 201a, 201b, 201c, and 201d.

Thereafter, at time T₃ which is the end time of the frame 1, the count value C1_5 of the counter circuit 211A is read out to the memory 212. The readout count value C1_5 is sequentially output from the photoelectric conversion device 100 via the buffer of the readout circuit 112.

In this manner, in the photoelectric conversion device 100 according to this embodiment, four APDs 201a, 201b, 201c, and 201d sharing one microlens 104 are arranged in the photoelectric converter 102 of one pixel 101. In addition, the counter circuits 211a, 211b, 211c, and 211d are arranged so as to correspond to the APDs 201a, 201b, 201c, and 201d, respectively. By using the connection circuit 220 to control the connection of the counter circuits 211a, 211b, 211c, and 211d, three types of count information, that is, signals corresponding to light beams respectively passing through the plurality of pupil regions divided in the vertical direction, those in the horizontal direction, and image information, can be acquired.

Similar to the first embodiment described above, in order to improve the accuracy of focusing information, time T₁ needs to be a timing when the counter circuits 211L and 211R do not saturate in the subframe 1-1. In addition, in order to improve the accuracy of focusing information, time T₂ needs to be a timing when the counter circuits 211T and 211B do not saturate in the subframe 1-2. The period length of each of the subframes 1-1, 1-2, and 1-3 may satisfy a formula similar to the above-described formula (1) or (1′).

FIG. 10 shows an example of the operation in which the counter circuits 211a, 211b, 211c, and 211d are switched in the order of the horizontal connection, the vertical connection, and the total connection. However, the order of the vertical connection, the horizontal connection, and the total connection may be used, or the total connection may be set first to acquire image information first. However, as described above, for example, in a case of using focusing information in focus detection, acquiring focusing information first can shorten the time required to achieve focusing, and improve the characteristics of the photoelectric conversion device 100.

The order of the horizontal connection frame and the vertical connection frame may be interchanged for each pixel 101 or for each appropriate region of the pixel region 12. For example, the order of the subframes may be changed for each frame, such as switching the subframes in the order of the horizontal connection and the vertical connection in the frame 1, and switching the subframes in the order of the vertical connection and the horizontal connection in the frame 2.

Here, all the counter circuits 211a, 211b, 211c, and 211d may be used as the independent 4-bit counter circuits, respectively, and signals therefrom may be summed to acquire a signal for focusing. However, in that case, the number of bits of the signal corresponding to a light beam passing through each of the plurality of pupil regions divided in the vertical direction and the horizontal direction is reduced from 8 bits to 5 bits. Therefore, using the connection circuit 220 as described above can improve the characteristics of the photoelectric conversion device 100.

Next, the third embodiment of the present disclosure will be described. In a photoelectric conversion device 100 according to this embodiment, one APD 201 is arranged in one pixel 101, and a plurality of counter circuits 211a, 211b, and 211c are arranged in a counter 200 with respect to one APD 201. In the photoelectric conversion device 100 according to this embodiment, movement information can be acquired from signals corresponding to the above-described first signal and second signal, and image information can be acquired from a signal corresponding to the third signal.

For example, Japanese Patent Laid-Open No. 2025-020014 describes that time-correlation imaging is performed by applying predetermined weighting to the output signal of an APD. Time-correlation imaging is a measurement method for acquiring the movement information of an object by acquiring time-modulated signals. The photoelectric conversion device 100 according to this embodiment can acquire a plurality of pieces of count information including movement information obtained by time-correlation imaging and image information while suppressing an increase in circuit scale.

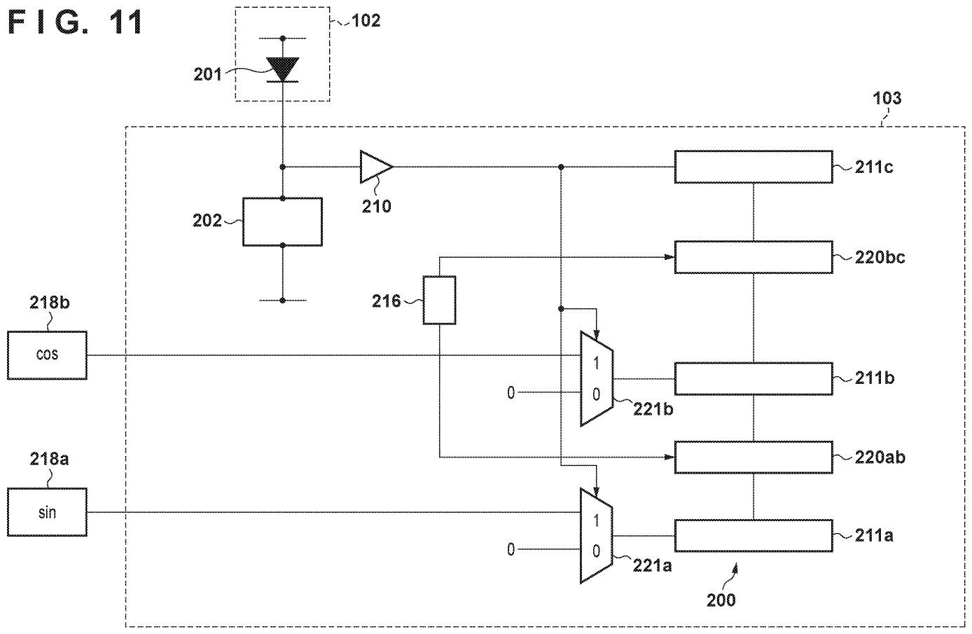

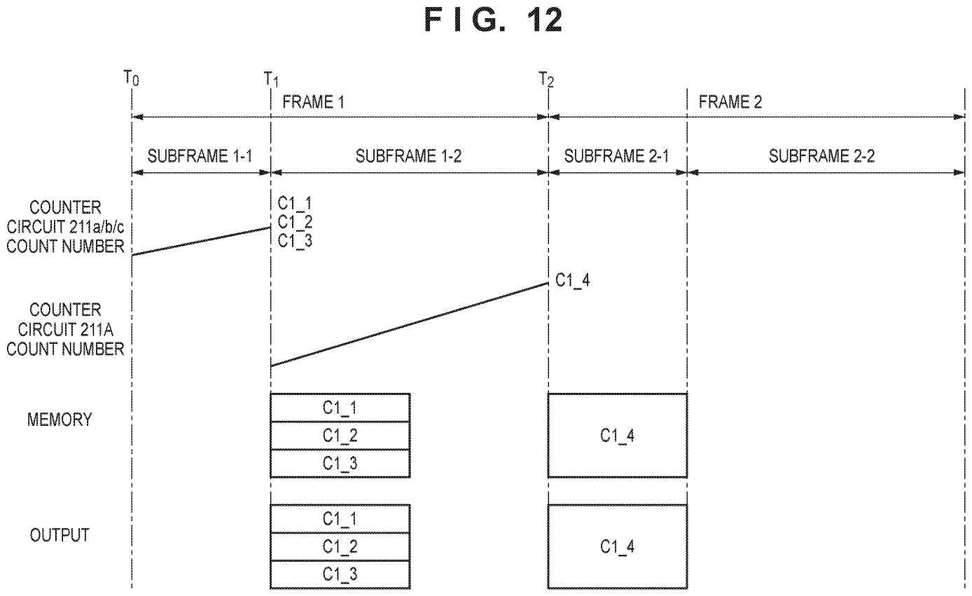

FIG. 11 is a view for explaining a configuration example of the photoelectric conversion device 100 according to this embodiment. The photoelectric conversion device 100 includes one APD 201 for each pixel 101, and the plurality of counter circuits 211a, 211b, and 211c are arranged for one APD 201. The following description will be given assuming that the number of bits countable by each of the counter circuits 211a, 211b, and 211c is 8 bits, but another number of bits may be used.

In the photoelectric conversion device 100 according to this embodiment, weighting controllers 218a and 218b, each of which applies weighting to the count value as the output of the APD 201, are arranged so as to correspond to the counter circuits 211a and 211b, respectively. The weighting controller 218a applies sin-waveform weighting to the output signal of the counter circuit 211a, and the weighting controller 218b applies cos-waveform weighting, which is different from the weighting applied by the weighting controller 218a, to the output signal of the counter circuit 211b. More specifically, multiplexer (MUX) circuits 221a and 221b may be arranged on the input sides of the counter circuits 211a and 211b, the output of the weighting controller 218a may be connected to one input of the MUX circuit 221a, and the output of the weighting controller 218b may be connected to one input of the MUX circuit 221b. With this, the outputs of the weighting controllers 218a and 218b at the time when a waveform shaping circuit 210 outputs a signal indicating that the APD 201 detects a photon are counted by the counter circuits 211a and 211b. For example, weighting may be applied to the count value by setting the signal input to a quench element 202 to have a sin waveform or a cos waveform. The counter circuit 211c counts the number of signals corresponding to incidence of photons to the APD 201 without applying any weighting. In the configuration shown in FIG. 11, the weighting controllers 218a and 218b are shown as separate components, but they may be integrated.

A connection circuit 220 includes a connection circuit 220ab that connects the counter circuit 211a and the counter circuit 211b, and a connection circuit 220bc that connects the counter circuit 211b and the counter circuit 211c. The connection circuits 220ab and 220bc are connected to a switch 216. When the switch 216 is in the OFF state, each of the counter circuits 211a, 211b, and 211c functions as an independent 8-bit counter circuit. By the weighting controllers 218a and 218b performing weighting, movement information obtained by time-correlation imaging can be acquired. On the other hand, when the switch 216 is in the ON state, the counter circuits 211a, 211b, and 211c connected by the connection circuit 220ab and the connection circuit 220bc function as a 24-bit counter circuit 211A, and image information can be acquired. When connecting three counter circuits 211a, 211b, and 211c and using them as the 24-bit counter circuit 211A, the weighting controllers 218a and 218b do not perform sin-waveform weighting and cos-waveform weighting. The outputs of the weighting controllers 218a and 218b are constantly set at Low and supplied to the MUX circuits 221a and 221b.

FIG. 12 is a view for explaining a method of acquiring movement information and image information by using the photoelectric conversion device 100 having the configuration shown in FIG. 11. At time T₀ which is the start time of a frame 1, the values of the counter circuits 211a, 211b, and 211c are reset, and the switch 216 is set in the OFF state. Then, in a subframe 1-1 from time T₀, while sin-waveform weighting is performed using the weighting controller 218a and cos-waveform weighting is performed using the weighting controller 218b, the counter circuits 211a, 211b, and 211c perform counting.

At time T₁ during the frame 1, count values C1_1, C1_2, and C1_3 of the counter circuits 211a, 211b, and 211c are read out to a memory 212. The readout count values C1_1, C1_2, and C1_3 are sequentially output from the photoelectric conversion device 100 via the buffer of a readout circuit 112. Movement information can be acquired from the output signals (count values C1_1 and C1_2).

At the same time, at time T₁, the count values of the counter circuits 211a, 211b, and 211c are reset, and the switch 216 is set in the ON state. The outputs of the weighting controllers 218a and 218b change to Low constantly. The connection circuits 220ab and 220ac connect the counter circuits 211a, 211b, and 211c to constitute the counter circuit 211A. Accordingly, the counter circuit 211A counts signals output from the APD 201 in a subframe 1-2.

At time T₂ which is the end time of the frame 1, a count value C1_4 of the counter circuit 211A is read out to the memory. The readout count value C1_4 is sequentially output from the photoelectric conversion device 100 via the buffer of the readout circuit 112. Image information can be acquired from the output signal (count value C1_4).

In this manner, in the photoelectric conversion device 100 according to this embodiment, one APD 201 is arranged in one pixel 101, and the plurality of counter circuits 211a, 211b, and 211c are arranged for one APD 201. The counter circuits 211a, 211b, and 211c can constitute the counter circuit 211A by the connection using the connection circuit 220. With this, the photoelectric conversion device 100 according to this embodiment can acquire a plurality of pieces of count information including movement information and image information while suppressing an increase in circuit scale.

FIG. 12 shows an example in which signals corresponding to the above-described first signal and second signal are acquired in the subframe 1-1, and a signal corresponding to the third signal is acquired in the subframe 1-2, but this order may be reversed. However, for example, in a case of using movement information of an object for tracking, acquiring movement information first from the first signal and the second signal can improve the tracking accuracy.

The signal counted by the counter circuit 211c in the subframe 1-1 does not undergo time modulation, so that image information can also be acquired from this signal. However, since the number of bits of the counter circuit 211c is smaller than the number of bits of the counter circuit 211A, the signal-to-noise ratio is low. Therefore, acquiring image information from the signal counted by the counter circuit 211A can improve the image quality.

In other words, the photoelectric conversion device described in Japanese Patent Laid-Open No. 2025-020014 can also acquire image information while performing time-correlation imaging, but the signal-to-noise ratio of the image information may deteriorate. On the other hand, by the connection circuit 220 controlling the connection of the counter circuits 211a, 211b, and 211c, the photoelectric conversion device 100 according to this embodiment can acquire image information with a high signal-to-noise ratio while performing time-correlation imaging.

Next, the fourth embodiment of the present disclosure will be described. A photoelectric conversion device 100 according to this embodiment includes one APD 201 and one counter circuit 211 for each pixel 101 (photoelectric converter 102). In the photoelectric conversion device 100 according to this embodiment, image information with a high resolution can be acquired from signals corresponding to the above-described first signal and second signal, and image information with a high signal-to-noise ratio can be acquired from a signal corresponding to the third signal.

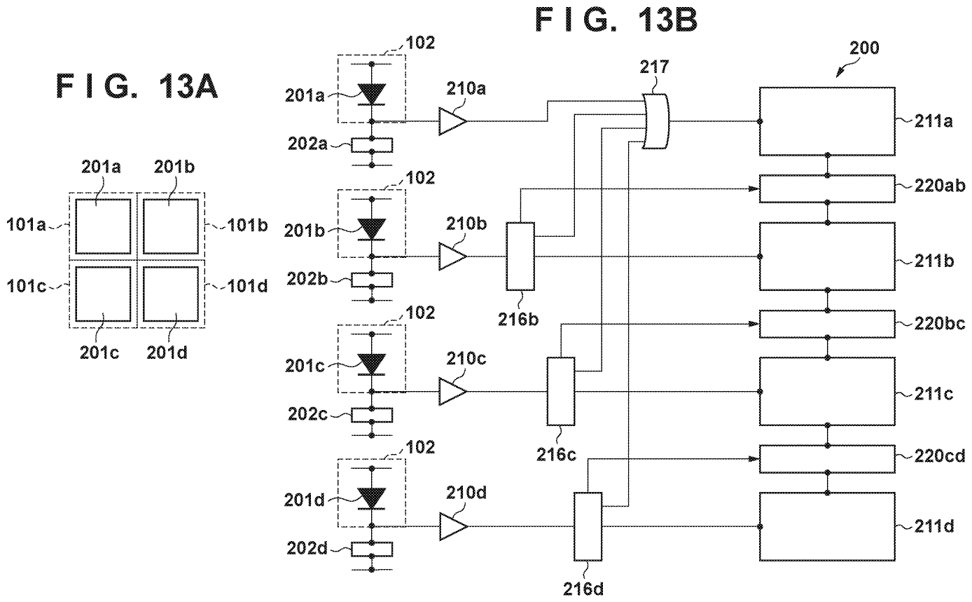

FIGS. 13A and 13B are views for explaining a configuration example of the photoelectric conversion device 100 according to this embodiment. The photoelectric conversion device 100 includes one APD 201 and one counter circuit 211 for each pixel 101. In the photoelectric conversion device 100 according to this embodiment, a connection circuit 220 is configured to be capable of controlling the connection of counter circuits 211a, 211b, 211c, and 211d of a plurality of pixels 101a, 101b, 101c, and 101d. The following description will be given assuming that the number of bits countable by each of the counter circuits 211a, 211b, 211c, and 211d is 4 bits, but another number of bits may be used.

The connection circuit 220 includes connection circuits 220ab, 220bc, and 220cd. The connection circuit 220ab connects the counter circuit 211a and the counter circuit 211b. The connection circuit 220bc connects the counter circuit 211b and the counter circuit 211c. The connection circuit 220cd connects the counter circuit 211c and the counter circuit 211d. The connection circuit 220 is controlled by switches 216b, 216c, and 216d. When the switches 216b, 216c, and 216d are set in the OFF state, each of the counter circuits 211a, 211b, 211c, and 211d corresponding to four pixels 101a, 101b, 101c, and 101d, respectively, functions as the independent 4-bit counter circuit. On the other hand, when the switches 216b, 216c, and 216d are set in the ON state, the connection circuits 220ab, 220bc, and 220cd connect the counter circuits 211a, 211b, 211c, and 211d. This causes the counter circuits 211a, 211b, 211c, and 211d to function as one 16-bit counter circuit 211A.

The switches 216b, 216c, and 216d also have a role of switching the connections between the cathodes of the APDs 201b, 201c, and 201d and the counter circuits. When the switches 216b, 216c, and 216d are set in the OFF state, the cathode of the APD 201a is connected to the counter circuit 211a, the cathode of the APD 201b is connected to the counter circuit 211b, the cathode of the APD 201c is connected to the counter circuit 211c, and the cathode of the APD 201d is connected to the counter circuit 211d. At the same time, the inputs from the switches 216b, 216c, and 216d to an OR circuit 217 are fixed at Low.

On the other hand, when the switches 216b, 216c, and 216d are set in the ON state, the cathodes of the APDs 201b, 201c, and 201d are connected to the inputs of the OR circuit 217. The cathode of the APD 201a is always connected to the input of the OR circuit 217. With this, if a photon enters one of the APDs 201a, 201b, 201c, and 201d, the count value at the counter circuit 211A increases by 1.

In this manner, by controlling the connection circuit 220, the photoelectric conversion device 100 according to this embodiment can acquire two types of different image information. The image information acquired when the switches 216b, 216c, and 216d are set in the OFF state has a high resolution since the number of signals corresponding to incidence of photons to each of the pixels 101a, 101b, 101c, and 101d is acquired independently. On the other hand, the image information acquired when the switches 216b, 216c, and 216d are set in the ON state has a high signal-to-noise ratio since a signal corresponding to incidence of a photon to any one of the plurality of pixels 101a, 101b, 101c, and 101d is detected and the number of bits of the counter circuit 211A is larger.

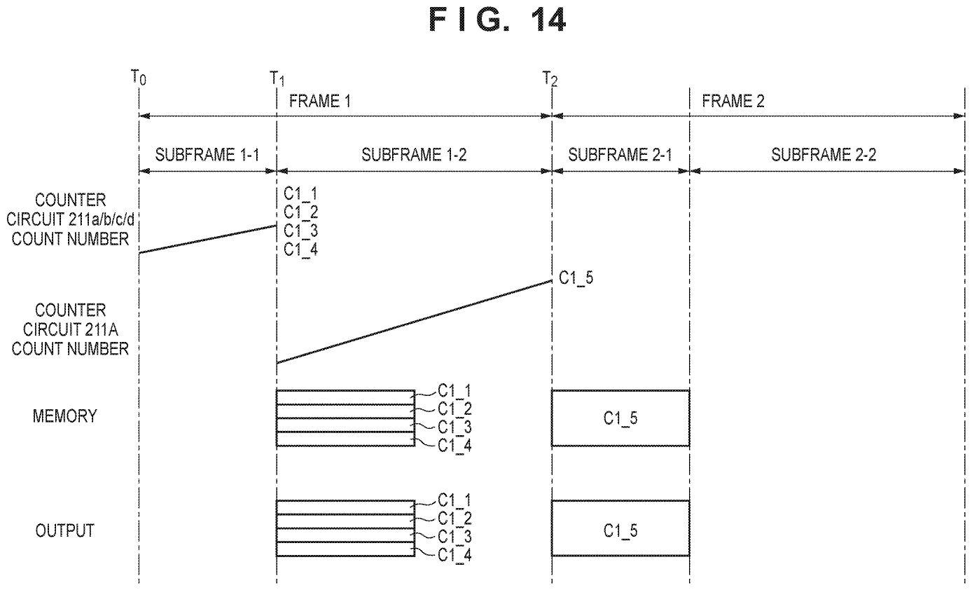

FIG. 14 is a view for explaining a method of acquiring a plurality of pieces of image information by using the photoelectric conversion device 100 having the configuration shown in FIGS. 13A and 13B. At time T₀ which is the start time of a frame 1, the values of the counter circuits 211a, 211b, 211c, and 211d are reset, and the switches 216b, 216c, and 216d are set in the OFF state. Then, in a subframe 1-1 from time T₀, each of the counter circuits 211a, 211b, 211c, and 211d counts the number of signals (count values C1_1, C1_2, C1_3, and C1_4) corresponding to incidence of photons to the APDs 201a, 201b, 201c, and 201d, respectively.

At time T₁ during the frame 1, the count values C1_1, C1_2, C1_3, and C1_4 of the counter circuits 211a, 211b, 211c, and 211d are read out to a memory 212. The readout count values C1_1, C1_2, C1_3, and C1_4 are sequentially output from the photoelectric conversion device 100 via the buffer of a readout circuit 112. The image information generated from the output signals (corresponding to the above-described first signal and second signal) has a low signal-to-noise ratio because the number of bits of the counter circuit is as small as 4 bits, but has a high resolution.

At the same time, at time T₁, the count values C1_1, C1_2, C1_3, and C1_4 of the counter circuits 211a, 211b, 211c, and 211d are reset, and the switches 216b, 216c, and 216d are set in the ON state. This connects the counter circuits 211a, 211b, 211c, and 211d, thereby causing them to constitute the counter circuit 211A. The counter circuit 211A counts the number of signals (count value C1_5) corresponding to incidence of photons to the APDs 201a, 201b, 201c, and 201d of four pixels 101a, 101b, 101c, and 101d.

At time T₂ which is the end time of the frame 1, the count value C1_5 of the counter circuit 211A is read out to the memory 212. The readout count value C1_5 is sequentially output from the photoelectric conversion device 100 via the buffer of the readout circuit 112. The image information generated from the output signal (corresponding to the above-described third signal) has a low resolution, but has a high signal-to-noise ratio because the number of bits of the counter circuit 211A is as large as 16 bits.

In this manner, in the photoelectric conversion device 100 according to this embodiment, the connection circuit 220 is not provided for each pixel 101 as in each embodiment described above, but the connection circuit 220 is provided between the counter circuits of the plurality of pixels 101. This enables acquisition of a plurality of pieces of count information which are image information different from each other.

Similar to each embodiment, in order to improve the accuracy of focusing information, time T₁ needs to be a timing when the counter circuits 211a, 211b, 211c, and 211d do not saturate in the subframe 1-1. Time T₁ may be decided to satisfy a formula similar to the above-described formula (1) or (1′). Then, the period length of a subframe 1-2 from time T₁ to time T₂ is longer than the period length of the subframe 1-1 from time T₀ to time T₁. As a result, the number of photons entering the APDs 201a, 201b, 201c, and 201d and counted by the counter circuit 211A can increase. That is, the signal-to-noise ratio can become higher.

In the configuration shown in FIGS. 13A and 13B, the connection circuit 220 connects the counter circuits 211 arranged so as to correspond to four pixels 101 arranged in a 2×2 array. In this manner, the connection circuit 220 may connect the counter circuits 211 provided for the APDs 201 (pixels 101) arranged adjacent to each other. Furthermore, the connection circuit 220 may connect the counter circuits 211 arranged so as to correspond to nine pixels 101 arranged in a 3×3 array or sixteen pixels 101 arranged in a 4×4 array. The pixels 101 for which the counter circuits 211 to be connected by the connection circuit 220 are arranged may be arranged in different numbers in the vertical direction and the horizontal direction, like a 1×2 array. In a case of the photoelectric conversion device 100 where the pixel 101 includes a color filter such as an on-chip color filter so that color information can be acquired, the connection circuit 220 may be provided so as to connect the counter circuits 211 of the pixels 101 where light transmitted through color filters of the same color enter.

Application examples of the above-described photoelectric conversion device 100 to a photoelectric conversion system and a moving body will be described below.

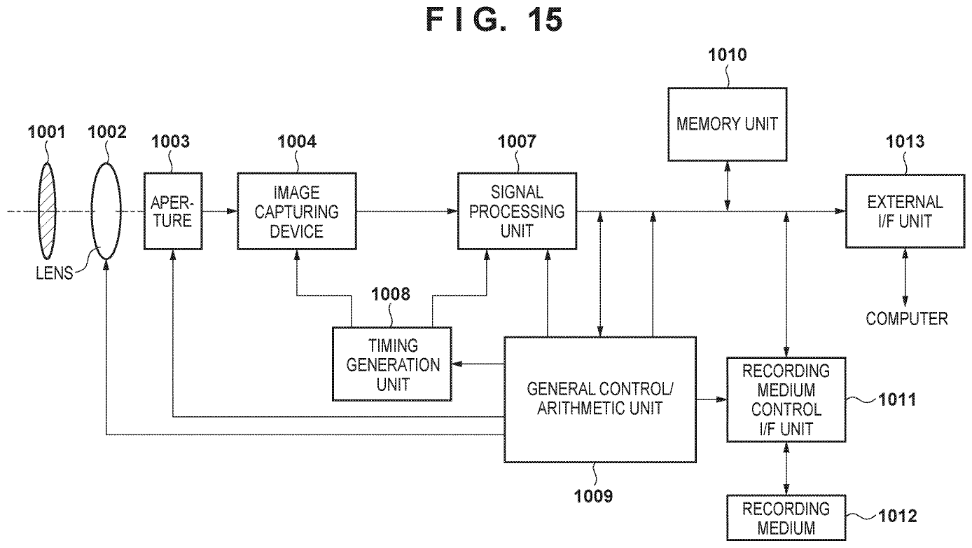

The photoelectric conversion device 100 described in each embodiment described above is applicable to various kinds of photoelectric conversion systems and the like. Examples of photoelectric conversion systems to which the photoelectric conversion device 100 is applicable are a digital still camera, a digital camcorder, a monitoring camera, a copying machine, a facsimile apparatus, a mobile phone, an in-vehicle camera, and an observation satellite. A camera module including an optical system such as a lens and an image capturing device is also included in the photoelectric conversion systems. FIG. 15 exemplarily shows the block diagram of a digital still camera as an example of these.

A photoelectric conversion system exemplarily shown in FIG. 15 includes an image capturing device 1004 as an example of the photoelectric conversion device 100, and a lens 1002 that forms an optical image of an object on the image capturing device 1004. The photoelectric conversion system further includes an aperture 1003 configured to change the amount of light passing through the lens 1002, and a barrier 1001 configured to protect the lens 1002. The lens 1002 and the aperture 1003 form an optical system that condenses light to the image capturing device 1004. The image capturing device 1004 may be the photoelectric conversion device 100 described in any one of the embodiments described above, and converts the optical image formed by the lens 1002 into an electrical signal. Here, the lens 1002 may include a focus lens. In that case, the photoelectric conversion device 100 according to the above-described first or second embodiment may be used as the image capturing device 1004. This is because the focus lens can be controlled using focusing information acquired by the photoelectric conversion device 100.

The photoelectric conversion system includes a signal processing unit 1007 that is an image generation unit configured to generate an image by processing an output signal output from the image capturing device 1004. The signal processing unit 1007 performs an operation of performing various kinds of correction and compression as needed, thereby outputting image data. The signal processing unit 1007 may be formed in a semiconductor layer where the image capturing device 1004 is provided, or may be formed in a semiconductor layer different from the image capturing device 1004. Alternatively, the image capturing device 1004 and the signal processing unit 1007 may be formed in the same semiconductor layer.

The photoelectric conversion system may further include a memory unit 1010 configured to temporarily store image data, and an external interface unit (external I/F unit) 1013 configured to communicate with an external computer or the like. Furthermore, the photoelectric conversion system may include a recording medium 1012 such as a semiconductor memory configured to record or read out image capturing data, and a recording medium control interface unit (recording medium control I/F unit) 1011 configured to perform record or readout for the recording medium 1012. The recording medium 1012 may be incorporated in the photoelectric conversion system or may be detachable.

Furthermore, the photoelectric conversion system includes a general control/arithmetic unit 1009 that controls various kinds of operations and the entire digital still camera, and a timing generation unit 1008 that outputs various kinds of timing signals to the image capturing device 1004 and the signal processing unit 1007. In this example, the timing signal and the like may be input from the outside, and the photoelectric conversion system need only include at least the image capturing device 1004, and the signal processing unit 1007 that processes an output signal output from the image capturing device 1004.

The image capturing device 1004 outputs an image capturing signal to the signal processing unit 1007. The signal processing unit 1007 executes predetermined signal processing for the image capturing signal output from the image capturing device 1004, and outputs image data. The signal processing unit 1007 can generate an image using the image capturing signal.

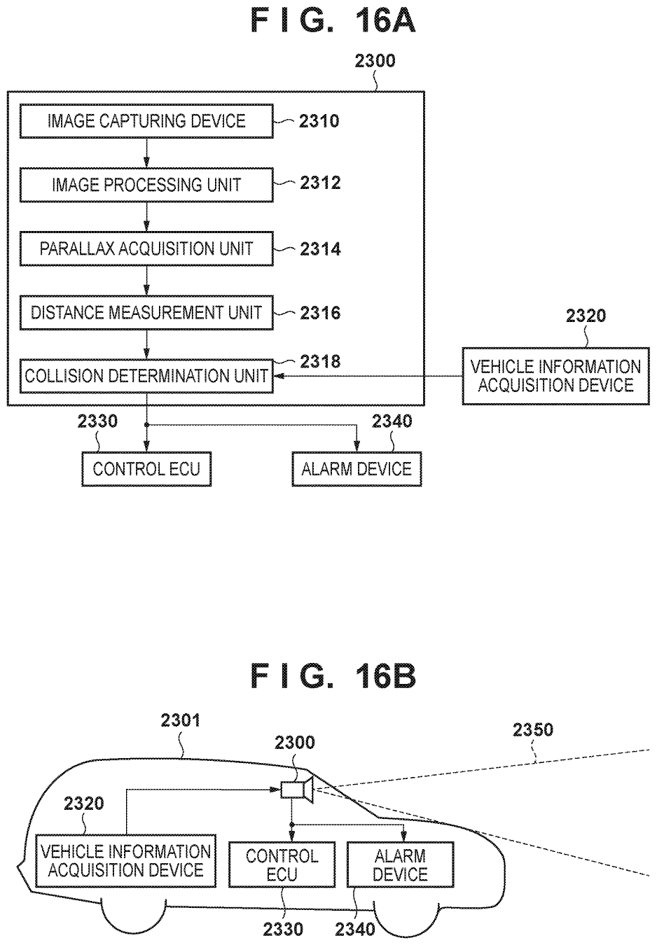

FIGS. 16A and 16B are views showing a configuration example of a photoelectric conversion system 2300 and a moving body 2301, which is an application example of the photoelectric conversion device 100 according to the embodiment. FIG. 16A shows an example of a photoelectric conversion system concerning an in-vehicle camera. The photoelectric conversion system 2300 includes an image capturing device 2310. The image capturing device 2310 can be the photoelectric conversion device 100 described in each embodiment described above. The photoelectric conversion system 2300 includes an image processing unit 2312 that performs image processing for a plurality of image data acquired by the image capturing device 2310. The photoelectric conversion system 2300 also includes a parallax acquisition unit 2314 that calculates a parallax (a phase difference between parallax images) from image data acquired by the photoelectric conversion system 2300. The photoelectric conversion system 2300 further includes a distance measurement unit 2316 that calculates the distance up to a target object based on the calculated parallax, and a collision determination unit 2318 that determines, based on the calculated distance, whether there is a possibility of collision. Here, the parallax acquisition unit 2314 and the distance measurement unit 2316 are examples of a distance information acquisition unit that acquires distance information up to a target object. By using the photoelectric conversion device 100 described in the above-described first or second embodiment for the image capturing device 2310, focusing information may be acquired. By a plurality of image capturing devices 2310 each using the photoelectric conversion device 100 described in the third or fourth embodiment, phase difference information may be acquired.

The collision determination unit 2318 may determine collision possibility using one of the pieces of distance information. Each of the parallax acquisition unit 2314 and the distance measurement unit 2316 may be implemented by exclusively designed hardware, or may be implemented by a software module. Each of the parallax acquisition unit 2314 and the distance measurement unit 2316 may be implemented by a Field Programmable Gate Array (FPGA), Application Specific Integrated Circuit (ASIC), or the like, or may be implemented by a combination of these. When the photoelectric conversion device 100 according to the third embodiment is used, the movement information of the object may be used in collision determination, in addition to the focusing information.

The photoelectric conversion system 2300 is connected to a vehicle information acquisition device 2320, and can acquire vehicle information such as a vehicle speed, a yaw rate, and a steering angle. The photoelectric conversion system 2300 is also connected to a control ECU 2330 that is a control device (controller) configured to output a control signal for generating a braking force to the vehicle based on the determination result of the collision determination unit 2318. Furthermore, the photoelectric conversion system 2300 is connected to an alarm device 2340 that generates an alarm to the driver based on the determination result of the collision determination unit 2318. For example, if collision possibility is high as the determination result of the collision determination unit 2318, the control ECU 2330 may perform braking, releasing the accelerator pedal, or suppressing the engine output, thereby controlling the vehicle for avoiding collision and reducing damage. The alarm device 2340 may sound an alarm such as a sound, display alarm information on the screen of a car navigation system or the like, or apply a vibration to the seat belt or a steering wheel, thereby giving an alarm to the user.

In this application example, the periphery of the vehicle (moving body 2301), for example, the front or rear side is captured by the photoelectric conversion system 2300. FIG. 16B shows the photoelectric conversion system when capturing the front side (image capturing range 2350) of the vehicle. The vehicle information acquisition device 2320 sends an instruction to the photoelectric conversion system 2300 or the image capturing device 2310. With this configuration, it is possible to further improve the accuracy of focusing measurement.

An example in which control is executed so as not to collide with another vehicle has been explained above. The photoelectric conversion system 2300 can also be applied to control of performing automated driving following another vehicle or control of performing automated driving without deviating from a lane. Furthermore, the photoelectric conversion system 2300 can be applied not only to a vehicle such as an automobile but also to, for example, a moving body (moving device) such as a ship, an airplane, a drone, or an industrial robot. The moving body includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, a propeller of an airplane, or the like. In addition, the photoelectric conversion system can be applied not only to a moving body but also to equipment that broadly uses object recognition, such as an intelligent transport system (ITS).

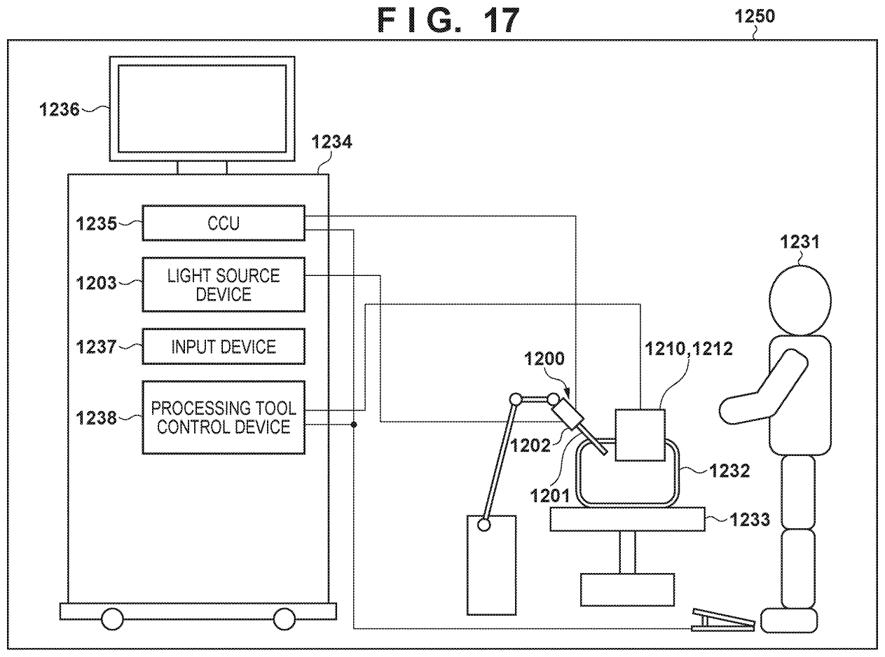

FIG. 17 is a view showing an example of the schematic configuration of an endoscopic surgery system 1250 as the photoelectric conversion system. FIG. 17 shows a state in which an operator (doctor) 1231 operates on a patient 1232 on a patient bed 1233 using the endoscopic surgery system 1250. As shown in FIG. 17, the endoscopic surgery system 1250 is formed from an endoscope 1200, a surgical tool 1210, and a cart 1234 on which various devices for endoscopic surgery are mounted.

The endoscope 1200 includes a lens barrel 1201 including a region of a predetermined length from the distal end, which is inserted into the body cavity of the patient 1232, and a camera head 1202 connected to the proximal end of the lens barrel 1201. In the example shown in FIG. 17, the endoscope 1200 formed as a so-called hard mirror including the hard lens barrel 1201 is shown but the endoscope 1200 may be formed as a so-called soft mirror including a soft lens barrel.

An opening in which an objective lens is fitted is provided at the distal end of the lens barrel 1201. A light source device 1203 is connected to the endoscope 1200, and light generated by the light source device 1203 is guided to the distal end of the lens barrel 1201 by a light guide extended inside the lens barrel 1201, and is emitted to an observation target in the body cavity of the patient 1232 via the objective lens. Note that the endoscope 1200 may be a forward-viewing endoscope or may be a forward-oblique viewing endoscope or side-viewing endoscope.

An optical system and a photoelectric conversion device are provided in the camera head 1202, and reflected light (observation light) from the observation target is condensed by the optical system to the photoelectric conversion device. The observation light is photoelectrically converted by the photoelectric conversion device to generate an electrical signal corresponding to the observation light, that is, an image signal corresponding to an observation image. As the photoelectric conversion device, the photoelectric conversion device 100 described in any of the above-described embodiments can be used. The image signal is transmitted as RAW data to a Camera Control Unit (CCU) 1235.

The CCU 1235 is formed by a Central Processing Unit (CPU), a Graphics Processing Unit (GPU), and the like, and comprehensively controls the operations of the endoscope 1200 and a display device 1236. Furthermore, the CCU 1235 receives an image signal from the camera head 1202, and performs, for the image signal, various kinds of image processes such as development processing (demosaic processing) for displaying an image based on the image signal.

Under the control of the CCU 1235, the display device 1236 displays the image based on the image signal having undergone the image processing by the CCU 1235.

The light source device 1203 is formed from a light source such as a Light Emitting Diode (LED), and supplies, to the endoscope 1200, irradiation light at the time of imaging an operation portion or the like.

An input device 1237 is an input interface to the endoscopic surgery system 1250. The user can input various kinds of information or instructions to the endoscopic surgery system 1250 via the input device 1237.

A treatment tool control device 1238 controls driving of an energy treatment tool 1212 for ablation or incision of the tissue, sealing of a blood vessel, or the like.

The light source device 1203 that supplies, to the endoscope 1200, irradiation light at the time of imaging an operation portion can be formed from, for example, a white light source formed by an LED, a laser light source, or a combination thereof. If the white light source is formed by a combination of RGB laser light sources, it is possible to accurately control the output intensity and output timing of each color (each wavelength), and thus the light source device 1203 can adjust the white balance of a captured image. In this case, the observation target is time-divisionally irradiated with laser beams from the RGB laser light sources, respectively, and driving of the image sensor of the camera head 1202 is controlled in synchronism with the irradiation timings, thereby making it possible to time-divisionally capture images respectively corresponding to R, G, and B. In this method, it is possible to obtain a color image without providing color filters in the image sensor.

Driving of the light source device 1203 may be controlled to change the intensity of light to be output for every predetermined time. It is possible to time-divisionally acquire images by controlling driving of the image sensor of the camera head 1202 in synchronism with the timing of changing the intensity of the light, and combine the images, thereby generating an image of a high dynamic range without so-called shadow detail loss or highlight detail loss.

The light source device 1203 may be configured to supply light in a predetermined wavelength band corresponding to special light observation. In special light observation, for example, the wavelength dependency of light absorption in the body tissue is used. More specifically, by performing irradiation with light in a narrow band, as compared with irradiation light (that is, white light) at the time of normal observation, predetermined tissue such as a blood vessel in the mucous membrane surface layer is captured with high contrast. Alternatively, in special light observation, fluorescence observation for obtaining an image by using fluorescence generated by performing radiation with excitation light may be performed. In fluorescence observation, it is possible to, for example, irradiate body tissue with excitation light and observe fluorescence from the body tissue, or locally inject a reagent such as indocyanine green (ICG) into body tissue while irradiating the body tissue with excitation light corresponding to the fluorescence wavelength of the reagent, thereby obtaining a fluorescence image. The light source device 1203 can be configured to supply narrow band light and/or excitation light corresponding to such special light observation.

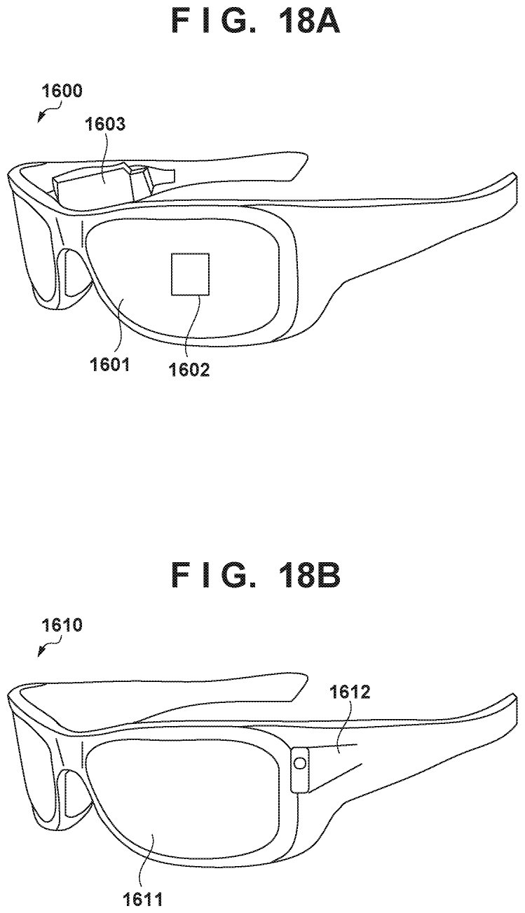

FIG. 18A describes glasses 1600 (smartglasses) as the photoelectric conversion system. The glasses 1600 include a photoelectric conversion device 1602. The photoelectric conversion device 1602 can be the photoelectric conversion device 100 described in any of the above-described embodiments. A display device including the light emitting device such as an OLED or LED may be provided on the back surface side of a lens 1601. One or a plurality of photoelectric conversion devices 1602 may be provided. Alternatively, a plurality of kinds of photoelectric conversion devices may be used in combination. The arrangement position of the photoelectric conversion device 1602 is not limited to that shown in FIG. 18A.

The glasses 1600 further include a control device 1603. The control device 1603 functions as a power supply that supplies electric power to the photoelectric conversion device 1602 and the above-described display device. In addition, the control device 1603 controls the operations of the photoelectric conversion device 1602 and the display device. An optical system configured to condense light to the photoelectric conversion device 1602 is formed on the lens 1601.

FIG. 18B describes glasses 1610 (smartglasses) according to an application example. The glasses 1610 include a control device 1612, and a photoelectric conversion device corresponding to the photoelectric conversion device 1602 and a display device are mounted on the control device 1612. The photoelectric conversion device in the control device 1612 and an optical system configured to project light emitted from the display device are formed in a lens 1611, and an image is projected to the lens 1611. The control device 1612 functions as a power supply that supplies electric power to the photoelectric conversion device and the display device, and controls the operations of the photoelectric conversion device and the display device. The control device may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to this application example can include a photoelectric conversion device including a light receiving element, and control a displayed image of the display device based on the line-of-sight information of the user from the photoelectric conversion device.

More specifically, the display device decides a first visual field region at which the user is gazing and a second visual field region other than the first visual field region based on the line-of-sight information. The first visual field region and the second visual field region may be decided by the control device of the display device, or those decided by an external control device may be received. In the display region of the display device, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority may be decided from the first display region and the second display region based on line-of-sight information. The first visual field region and the second visual field region may be decided by the control device of the display device, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target object ahead the line of sight from the image of the eyeball using the image of the eyeball and the direction of actual viewing of the eyeball in the image as supervised data. The AI program may be held by the display device, the photoelectric conversion device, or an external device. If the external device holds the AI program, the first visual field region or the region of higher priority is transmitted to the display device via communication.

When performing display control based on line-of-sight detection, smartglasses further including a photoelectric conversion device configured to capture the image of the outside can be applied. The smartglasses can display the captured outside image information in real time.

According to the present disclosure, a technique advantageous in suppressing the circuit scale can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-082856, filed May 16, 2025, which is hereby incorporated by reference herein in its entirety.

What is claimed is:

1. A photoelectric conversion device that comprises a photoelectric converter including an avalanche photodiode (APD), and a counter configured to perform counting corresponding to a number of signals output from the photoelectric converter, wherein
the counter includes a first count circuit, a second count circuit, and a connection circuit,
by the connection circuit connecting the first count circuit and the second count circuit, the first count circuit and the second count circuit are configurable to constitute a third count circuit capable of counting a sum of at least a part of a number of bits countable by the first count circuit and at least a part of a number of bits countable by the second count circuit, and
in a case of constituting the third count circuit, the connection circuit is configured to connect a most significant bit of the first count circuit and a least significant bit of the second count circuit, or connect a least significant bit of the first count circuit and a most significant bit of the second count circuit.

2. The photoelectric conversion device according to claim 1, wherein
the photoelectric conversion device executes a plurality of unit sequences, and
each of the plurality of unit sequences includes a plurality of subframes including a first subframe during which the connection circuit does not connect the first count circuit and the second count circuit, and a second subframe during which the connection circuit connects the first count circuit and the second count circuit to constitute the third count circuit.

3. The photoelectric conversion device according to claim 2, wherein
the photoelectric converter includes a plurality of APDs including a first APD and a second APD,
in the first subframe, the first count circuit counts a signal output from the first APD, and the second count circuit counts a signal output from the second APD, and
in the second subframe, the third count circuit counts signals output from the first APD and the second APD.

4. The photoelectric conversion device according to claim 3, wherein
the first APD and the second APD share one microlens.

5. The photoelectric conversion device according to claim 4, wherein
the plurality of APDs further include a third APD and a fourth APD,
the first APD, the second APD, the third APD, and the fourth APD share the microlens,
in the first subframe, the first count circuit counts signals output from the first APD and the third APD, and the second count circuit counts signals output from the second APD and the fourth APD, and
in the second subframe, the third count circuit counts signals output from the first APD, the second APD, the third APD, and the fourth APD.

6. The photoelectric conversion device according to claim 5, wherein
the first count circuit is configured to include a fourth count circuit and a fifth count circuit connected by the connection circuit, and the second count circuit is configured to include a sixth count circuit and a seventh count circuit connected by the connection circuit,
the connection circuit is configurable to cause the fourth count circuit and the sixth count circuit to constitute an eighth count circuit capable of counting a sum of a number of bits countable by the fourth count circuit and a number of bits countable by the sixth count circuit, and the connection circuit is configurable to cause the fifth count circuit and the seventh count circuit to constitute a ninth count circuit capable of counting a sum of a number of bits countable by the fifth count circuit and a number of bits countable by the seventh count circuit,
the plurality of subframes further include a third subframe during which the connection circuit connects the fourth count circuit and the sixth count circuit to constitute the eighth count circuit, and the connection circuit connects the fifth count circuit and the seventh count circuit to constitute the ninth count circuit, and
in the third subframe, the eighth count circuit counts signals output form the first APD and the second APD, and the ninth count circuit counts signals output from the third APD and the fourth APD.

7. The photoelectric conversion device according to claim 6, wherein
in each unit sequence, a period of the first subframe and a period of the third subframe precede a period of the second subframe.

8. The photoelectric conversion device according to claim 3, wherein light transmitted through a color filter of the same color enters the first APD and the second APD.

9. The photoelectric conversion device according to claim 8, wherein
the first count circuit is configured to include a fourth count circuit and a fifth count circuit connected by the connection circuit, and the second count circuit is configured to include a sixth count circuit and a seventh count circuit connected by the connection circuit,
the plurality of APDs further include a third APD and a fourth APD,
light transmitted through a color filter of the same color enters the first APD, the second APD, the third APD, and the fourth APD,
in the first subframe, the fourth count circuit counts a signal output from the first APD, the fifth count circuit counts a signal output from the third APD, the sixth count circuit counts a signal output form the second APD, and the seventh count circuit counts a signal output from the fourth APD.

10. The photoelectric conversion device according to claim 9, wherein
the first APD, the second APD, the third APD, and the fourth APD are arranged adjacent to each other.

11. The photoelectric conversion device according to claim 2, further comprising a weighting controller configured to apply weighting to an output of the APD,
wherein, in the first subframe, the first count circuit counts a signal obtained by the weighting controller applying first weighting to an output of the APD, and the second count circuit counts a signal obtained by the weighting controller applying, to an output of the APD, second weighting different from the first weighting.

12. The photoelectric conversion device according to claim 11, wherein
in the second subframe,
the third count circuit counts a signal output from the APD, and
the weighting controller does not apply weighting.

13. The photoelectric conversion device according to claim 11, wherein
the counter further includes a fourth count circuit,
in the first subframe, the fourth count circuit counts a signal output from the APD and not applied with weighting by the weighting controller, and
in the second subframe, the connection circuit causes the fourth count circuit to constitute a part of the third count circuit.

14. The photoelectric conversion device according to claim 2, wherein
in each unit sequence, a period of the first subframe precedes a period of the second subframe.

15. The photoelectric conversion device according to claim 2, wherein
a period of the first subframe is shorter than a period of the second subframe.

16. The photoelectric conversion device according to claim 2, wherein
assuming that L1 [msec] is a period length of the first subframe, L2 [msec] is a period length of the second subframe, and the number of bits countable by the first count circuit and the number of bits countable by the second count circuit are the same and indicated by B [bit],
L1≤(½^{B})×L2
is satisfied.

17. The photoelectric conversion device according to claim 1, wherein
by the connection circuit connecting the first count circuit and the second count circuit, the first count circuit and the second count circuit are configurable to constitute a third count circuit capable of counting a sum of the total number of bits countable by the first count circuit and the total number of bits countable by the second count circuit.

18. A photoelectric conversion system comprising:
the photoelectric conversion device according to claim 1; and
a signal processing unit configured to generate an image using a signal output from the photoelectric conversion device.

19. A moving body that includes the photoelectric conversion device according to claim 1, comprising
a controller configured to control movement of the moving body by using a signal output from the photoelectric conversion device.

20. A photoelectric conversion device that comprises a photoelectric converter including an avalanche photodiode (APD), and a counter configured to perform counting corresponding to the number of signals output from the photoelectric converter, wherein
the counter includes a first count circuit, a second count circuit, and a connection circuit,
by the connection circuit connecting the first count circuit and the second count circuit, the first count circuit and the second count circuit are configurable to constitute a third count circuit capable of counting a sum of at least a part of a number of bits countable by the first count circuit and at least a part of a number of bits countable by the second count circuit,
the photoelectric conversion device executes a plurality of unit sequences, and
each of the plurality of unit sequences includes a plurality of subframes including a first subframe during which the connection circuit does not connect the first count circuit and the second count circuit, and a second subframe during which the connection circuit connects the first count circuit and the second count circuit to constitute the third count circuit.
